(19) United States
(12) Patent Application Publication
(10) Pub. No.: US 2026/0360453 A1
(43) Pub. Date: Nov. 12, 2026

(54) MEMORY DEVICE HAVING TEST FUNCTION AND TEST METHOD THEREOF

(71) Applicant: Winbond Electronics Corp., Taichung City (TW)

(72) Inventor: Sang Bum Park, Taipei (TW)

(73) Assignee: Winbond Electronics Corp., Taichung City (TW)

(21) Appl. No.: 19/200,611

(22) Filed: May 6, 2025

(51) Int. Cl. G11C 29/12

(52) U.S. Cl. CPC G11C 29/12005

(57) ABSTRACT

The disclosure provides a memory device having test function and a test method of the memory device. The memory device includes a memory array and a test circuit. The memory array includes memory cells. The test circuit includes a select circuit, a current receiver and a converter. The select circuit selects one of the memory cells sequentially. The current receiver obtains cell current values of the memory cells sequentially. The converter converts the cell current values to current data of the memory cells sequentially. The test circuit outputs a test result according to the current data.

### BACKGROUND

### Technical Field

The disclosure generally relates to a memory device and a test method of the memory device, and more particularly to a memory device having test function and a test method of the memory device.

### Description of Related Art

Generally, cell currents of a memory device are tested or verified by an external test device. In a test or verify process, the memory device selects one of memory cells and outputs a cell current of selected memory cell. The external test device receives the cell current outputted by the memory device, measures a current value of the cell current, and the record the current value of the cell current. Then, the memory device selects next one of memory cells and outputs a cell current of next selected memory cell.

It should be noted, the external test device need takes 3 seconds to 5 seconds to obtain one cell current and record one current value. Thus, it must take quite a long time to collect all of the cell currents of the memory device. Therefore, how to decrease a test time of the memory device is one of the research and development focuses of those skilled in the art.

### SUMMARY

The disclosure provides a memory device having test function and a test method of the memory device. The memory device can perform a self-test function to decrease a test time.

In an embodiment of the disclosure, the memory device includes a memory array and a test circuit. The memory array includes memory cells. The test circuit includes a select circuit, a current receiver and a converter. The select circuit is connected to the memory array. The select circuit selects one of the memory cells sequentially. The current receiver is connected to the select circuit. The current receiver obtains cell current values of the memory cells sequentially. The converter is connected to the current receiver. The converter converts the cell current values to current data of the memory cells sequentially. The test circuit outputs a test result according to the current data.

In an embodiment of the disclosure, the test method is used for a memory device. The memory device comprises a memory array and a test circuit. The memory array comprises memory cells. The test method comprises: selecting, by the test circuit, one of the memory cells sequentially; obtaining, by the test circuit, cell current values of the memory cells sequentially; converting, by the test circuit, the cell current values to current data of the memory cells sequentially; and outputting a test result according to the current data.

Based on the above, the test circuit in the memory device obtains the cell current values of the memory cells sequentially and converts the cell current values to the current data of the memory cells sequentially. The memory device can perform a self-test function to decrease a test time. Therefore, the cell currents of the memory cells are not obtained by an external test device. The cell current values are not measured by an external test device. In this way, the memory device decreases the test time for verifying the cell currents of the memory cells.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 illustrates a schematic diagram of a memory device according to an embodiment of the disclosure.

FIG. 2 illustrates a schematic diagram of a memory device according to an embodiment of the disclosure.

FIG. 3 illustrates a schematic diagram of a test result according to an embodiment of the disclosure.

FIG. 4 illustrates a schematic diagram of a test result according to an embodiment of the disclosure.

FIG. 5 illustrates a schematic diagram of a current data according to an embodiment of the disclosure.

FIG. 6 illustrates a schematic diagram of a converter according to an embodiment of the disclosure.

FIG. 7 illustrates a schematic diagram of a converter according to an embodiment of the disclosure.

FIG. 8 illustrates a flow chart of a test method according to an embodiment of the disclosure.

### DESCRIPTION OF THE EMBODIMENTS

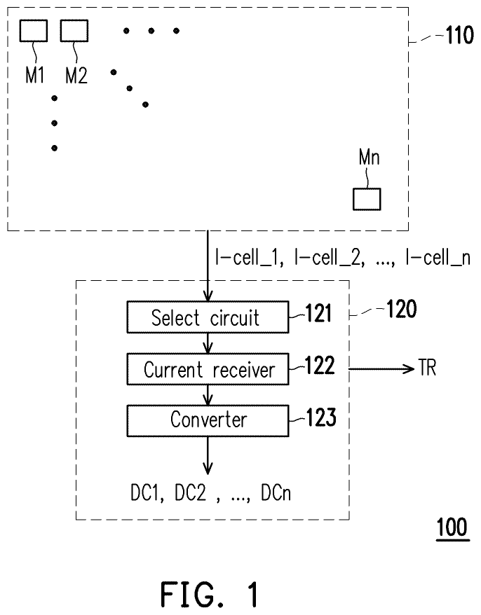

Please refer to FIG. 1, a memory device 100 includes a memory array 110 and a test circuit 120. The memory array 110 includes memory cells M1 to Mn. The test circuit 120 includes a select circuit 121, a current receiver 122 and a converter 123. The select circuit 121 is connected to the memory array 110. The select circuit 121 selects one of the memory cells M1 to Mn sequentially. The current receiver 122 is connected to the select circuit 121. The current receiver 122 obtains cell current values I-cell_1 to I-cell_n of the memory cells M1 to Mn sequentially. The converter 123 is connected to the current receiver 122. The converter 123 converts the cell current values I-cell_1 to I-cell_n to current data DC1 to DCn of the memory cells M1 to Mn sequentially.

The select circuit 121 may select one of the memory cells M1 to Mn sequentially to be a selected memory cell based on a test pattern. For example, the select circuit 121 selects the memory cell M1 and then selects the memory cell M2 sequentially based a test pattern. When the memory cell M1 is selected by the select circuit 121, the current receiver 122 obtains the cell current value I-cell_1 of the memory cell M1, and then the converter 123 converts the cell current value I-cell_1 to the current data DC1.

After the current data DC1 is obtained, the select circuit 121 selects the memory cell M2. When the memory cell M2 is selected, the current receiver 122 obtains the cell current value I-cell_2 of the memory cell M2, and then the converter 123 converts the cell current value I-cell_2 to the current data DC2.

Besides, the test circuit 120 outputs a test result TR according to the current data DC1 to DCn.

It should be noted, the test circuit 120 in the memory device 100 obtains the cell current values I-cell_1 to I-cell_n of the memory cells M1 to Mn sequentially, and converts the cell current values I-cell_1 to I-cell_n to the current data DC1 to DCn of the memory cells M1 to Mn sequentially. The memory device 100 can perform a self-test function to decrease a test time. Therefore, the cell currents of the memory cells M1 to Mn are not obtained by an external test device. The cell current values I-cell_1 to I-cell_n are not measured by an external test device. In this way, the memory device 100 can decrease the test time for verifying the cell currents of the memory cells M1 to Mn.

In some embodiment, memory device 100 includes memory banks. The test circuit 120 is used for at least one memory bank.

In the embodiment, each of the cell current values I-cell_1 to I-cell_n is an analog signal. Each of the current data DC1 to DCn is a digital signal. Thus, the converter 123 may be implemented by an analog-to-digital converter (ADC).

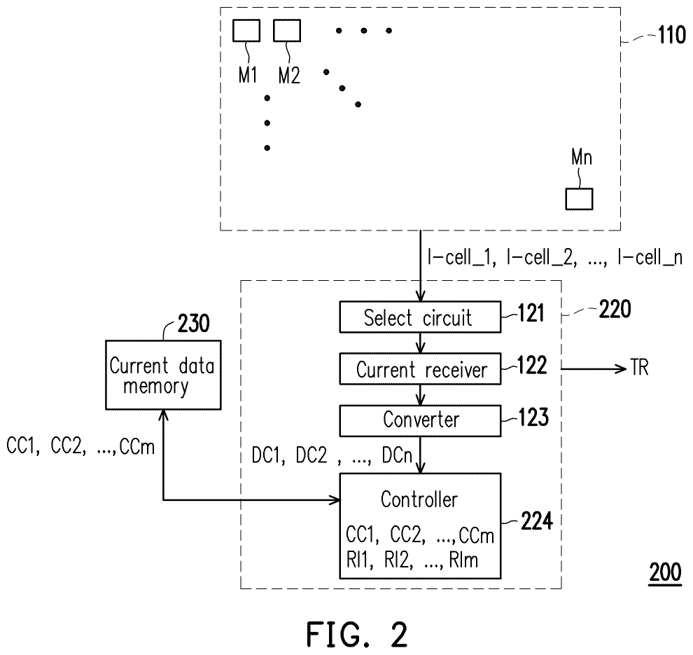

Please refer to FIG. 2, a memory device 200 includes the memory array 110, the test circuit 220 and a current data memory 230. The test circuit 220 counts numbers of the memory cells corresponding to cell current value ranges RI1 to RIm to generate count values CC1 to CCm according to the current data DC1 to DCn, and outputs the test result TR according to the count values CC1 to CCm.

The test circuit 220 includes the select circuit 121, the current receiver 122, the converter 123 and a controller 224. The controller 224 is connected to the converter 123. The controller 224 receives the current data DC1 to DCn from the converter 123 sequentially. The controller 224 counts numbers of the memory cells corresponding to cell current value ranges RI1 to RIm to generate the count values CC1 to CCm according to the current data DC1 to DCn. For example, the controller 224 may counts a first memory cell number corresponding to the cell current value range RI1 to generate the count value CC1 according to the current data DC1 to DCn. The controller 224 may counts a second memory cell number corresponding to the cell current value range RI2 to generate the count value CC2 according to the current data DC1 to DCn, and so on.

The operation of the select circuit 121, the current receiver 122 and the converter 123 has been clearly explained in the embodiments of FIG. 1, so it will not be repeated here.

The current data memory 230 is connected to the controller 224. The current data memory 230 stores the count values CC1 to CCm corresponding to the cell current value ranges RI1 to RIm. For example, when the controller 224 obtains a current data corresponding to the cell current value range RI1, the controller 224 increments the count values CC1 corresponding to the cell current value range RI1. For example, when the controller 224 obtains a current data corresponding to the cell current value range RI2, the controller 224 increments the count values CC2 corresponding to the cell current value range RI2.

In some embodiments, the current data memory 230 could be integrated in the test circuit 220.

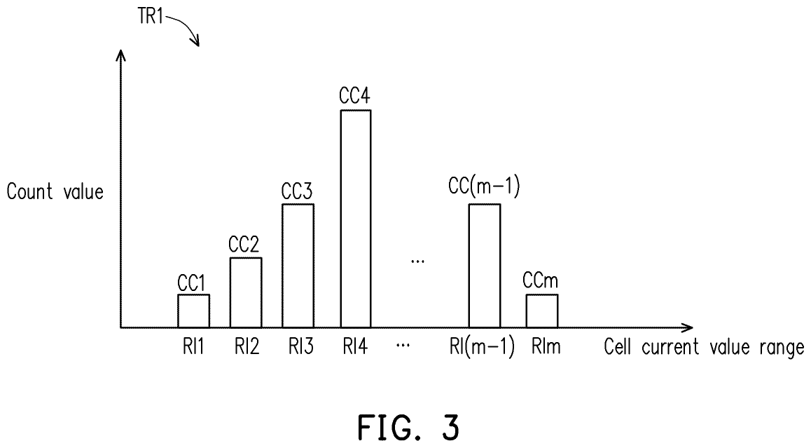

Please refer to FIG. 2 and FIG. 3, FIG. 3 illustrates a test result TR1 for verifying the cell currents of the memory cells M1 to Mn. The test result TR1 illustrates the count values CC1 to CCm corresponding to the cell current value ranges RI1 to RIm based on specific access voltage (for example, a fixed read voltage). For example, the cell current value range RI1 is in a range of 0 microampere (μA) to 2 μA. The cell current value range RI2 is in a range of 2 μA to 10 μA. The cell current value range RI2 is in a range of 10 μA to 20 μA. But the disclosure is not limited thereto, and so on.

For example, the count value CC1 is the first memory cell number corresponding to the cell current value range RI1. The count value CC2 is the second memory cell number corresponding to the cell current value range RI2. Similarly, the count value CC(m−1) is a (m−1)th memory cell number corresponding to the cell current value range RI(m−1). The count value CCm is a (m)th memory cell number corresponding to the cell current value range RIm.

In the embodiment, the test result TR1 is a histogram.

In the embodiment, the test circuit 220 can obtain a fail-bit count (FBC) of the memory array 110 according to the count values CC1 to CCm. For example, the cell current value ranges RI1, RI2, RI(m−1) and RIm are fail cell current value ranges, but the disclosure is not limited thereto. Therefore, the test circuit 220 can obtain the FBC of the memory array 110 according to a sum of the count values CC1, CC2, CC(m−1) and CCm (that is, FBC=CC1+CC2+CC(m−1)+CCm).

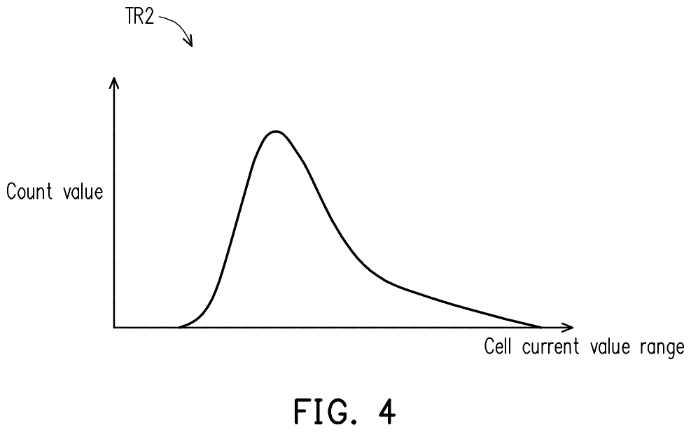

Please refer to FIG. 2 and FIG. 4, FIG. 4 illustrates a test result TR2 for verifying the cell currents of the memory cells M1 to Mn. The test result TR2 is a distribution diagram of the count values corresponding to different cell current value.

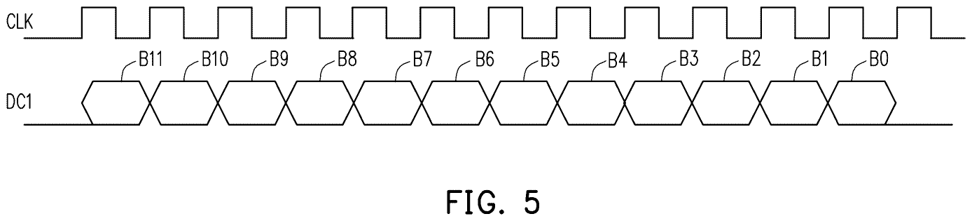

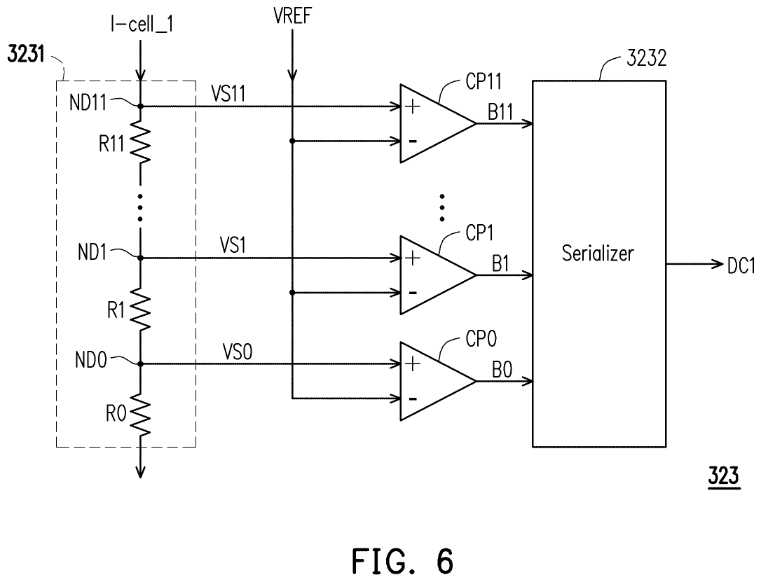

Please refer to FIG. 1, FIG. 5 and FIG. 6, FIG. 5 illustrates a current data DC1. FIG. 6 illustrates a converter 323. Taking the cell current value I-cell_1 as an example, the converter 323 converts the cell current value I-cell_1 to the current data DC1 having a serial format. The current data DC1 includes code bits B0 to B11. When the converter 323 receives the cell current value I-cell_1, the converter 323 converts the cell current value I-cell_1 to sensing voltages VS0 to VS11. The converter 323 converts the sensing voltages VS0 to VS11 to the current data DC1 having the serial format.

In the embodiment, the converter 323 includes a resistor string 3231, comparators CP0 to CP11 and a serializer 3232. The resistor string 3231 is connected between the current receiver 122 and a reference low voltage. The resistor string 3231 includes resistors R0 to R11 connected in series each other through nodes ND0 to ND11. Each of the nodes ND0 to ND11 outputs the sensing voltage having different voltage value. In the embodiment, the resistor string 3231 receives the cell current value I-cell_1 and outputs the sensing voltages VS0 to VS11.

The resistors R0 is connected between the node ND0 and the reference low voltage. The resistors R1 is connected between the node ND1 and the node ND0, and so on. The node ND0 outputs the sensing voltage VS0. The node ND1 outputs the sensing voltage VS1. Similarly, the node ND11 outputs the sensing voltage VS11. A voltage value of the sensing voltage VS0 is lower than a voltage value of the sensing voltage VS1.

In the embodiment, each of the resistors R0 to R11 has a same resistance value.

The comparators CP0 to CP11 are connect to the nodes ND0 to ND11 in one by one manner. The comparators CP0 to CP11 compare a received sensing voltage and a reference voltage VREF to generate the code bits B0 to B11 of the current data DC1 respectively. The serializer 3232 is connected to the comparators CP0 to CP11. The serializer 3232 generates the current data DC1 having the serial format according to the sensing voltages VS0 to VS11.

In the embodiment, the comparator CP0 is connected to the node ND0. The comparator CP0 compares the sensing voltage VS0 and the reference voltage VREF to generate the code bit B0. The comparator CP1 is connected to the node ND1. The comparator CP1 compares the sensing voltage VS1 and the reference voltage VREF to generate the code bit B1. Similarly, the comparator CP11 is connected to the node ND11. The comparator CP11 compares the sensing voltage VS11 and the reference voltage VREF to generate the code bit B11.

Taking the comparator CP0 as an example, a non-inverting terminal of the comparator CP0 is connected to the node ND0. An inverting terminal of the comparator CP0 receives the reference voltage VREF. When the voltage value of the sensing voltage VS0 is higher than a voltage value of the reference voltage VREF, the code bit B0 has a first logic level. When the voltage value of the sensing voltage VS0 is lower than or equal to the voltage value of the reference voltage VREF, the code bit B0 has a second logic level.

Therefore, in the current data DC1, the more bits having the first logic level, the higher the cell current value I-cell_1 is. The more bits having the second logic level, the lower the cell current value I-cell_1 is.

For example, the first logic level is logic “1”. The second logic level is logic “0”. For another example, the first logic level is logic “0”. The second logic level is logic “1”.

The serializer 3232 receives the sensing voltages VS0 to VS11 in a parallel manner and generates the current data DC1 having the serial format. Thus, the serializer 3232 may be implemented by a parallel-to-serial converter.

In the embodiment, the serializer 3232 generates the current data DC1 having the serial format based on a clock CLK. For example, the serializer 3232 outputs code bits B0 to B11 of the current data DC1 sequentially based on a period of the clock CLK.

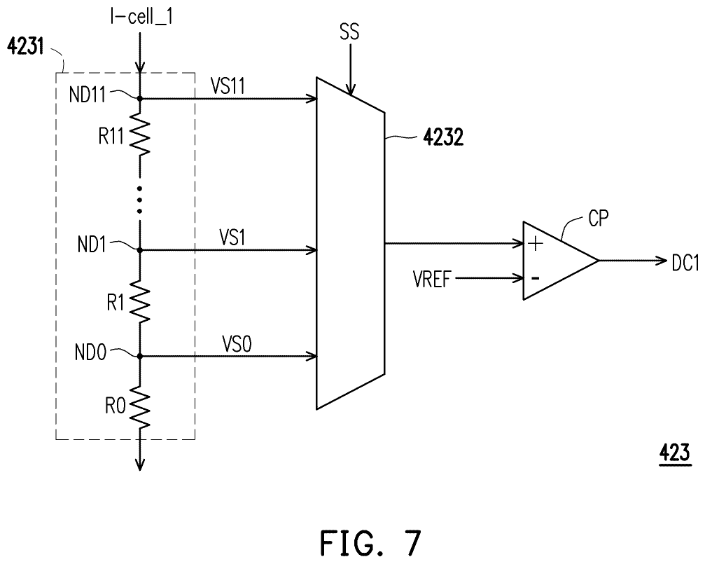

Please refer to FIG. 1, FIG. 5 and FIG. 7, FIG. 7 illustrates a converter 423. Taking the cell current value I-cell_1 as an example, the converter 423 converts the cell current value I-cell_1 to the current data DC1 having a serial format. The current data DC1 includes code bits B0 to B11. When the converter 423 receives the cell current value I-cell_1, the converter 423 converts the cell current value I-cell_1 to sensing voltages VS0 to VS11. The converter 423 converts the sensing voltages VS0 to VS11 to the current data DC1 having the serial format.

The converter 423 includes a resistor string 4231, a multiplexer 4232 and a comparator CP. The resistor string 4231 is connected between the current receiver 122 and a reference low voltage. The resistor string 4231 includes the resistors R0 to R11 connected in series each other through nodes ND0 to ND11. Each of the nodes ND0 to ND11 outputs the sensing voltage having different voltage value. In the embodiment, the resistor string 4231 receives the cell current value I-cell_1 and outputs the sensing voltages VS0 to VS11.

The resistors R0 is connected between the node ND0 and the reference low voltage. The resistors R1 is connected between the node ND1 and the node ND0, and so on. The node ND0 outputs the sensing voltage VS0. The node ND1 outputs the sensing voltage VS1, and so on.

The multiplexer is connected to the nodes ND0 to ND11, and selects one of the sensing voltages VS0 to VS11 as an output sensing voltage sequentially according to a select signal SS. For example, the multiplexer 4232 selects the sensing voltage VS0 as the output sensing voltage and then selects the sensing voltage VS1 as the output sensing voltage and then selects the sensing voltage VS2 as the output sensing voltage, and so on.

The comparator CP is connected to the multiplexer 4232. The comparator CP compares the output sensing voltage and the reference voltage VREF to generate a code bit of current data DC1 respectively. The comparator CP compares the output sensing voltage corresponding to the sensing voltage VS0 and the reference voltage VREF to generate the code bit B0, and then compares the output sensing voltage corresponding to the sensing voltage VS1 and the reference voltage VREF to generate the code bit B1.

A non-inverting terminal of the comparator CP is connected to an output terminal of the multiplexer 4232. An inverting terminal of the comparator CP receives the reference voltage VREF. When the voltage value of the output sensing voltage corresponding to the sensing voltage VS0 is higher than a voltage value of the reference voltage VREF, the code bit B0 has the first logic level. When the voltage value of the output sensing voltage corresponding to the sensing voltage VS0 is lower than or equal to the voltage value of the reference voltage VREF, the code bit B0 has the second logic level.

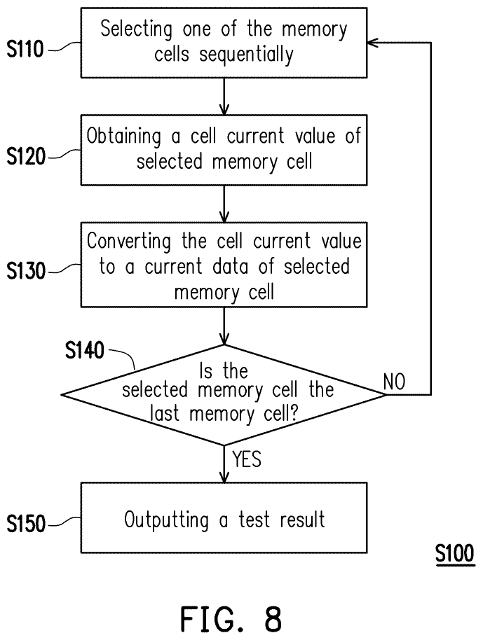

Please refer to FIG. 1 and FIG. 8, A test method S100 could be used for the memory device 100. The test circuit 120 in the memory device 100 performs the test method S100. The test method S100 includes steps S110 to S150. In the step S110, the select circuit 121 selects one of the memory cells M1 to Mn sequentially as a selected memory cell. In the step S120, the current receiver 122 obtains a cell current value of the selected memory cell. In the step S130, the converter 123 converts the cell current value of the selected memory cell to the current data of the selected memory cell.

In the step S140, the test circuit 120 determines whether the selected memory cell is the last memory cell. When the selected memory cell is not the last memory cell, the select circuit 121 selects next one of the memory cells M1 to Mn sequentially in the step S110. Therefore, the current receiver 122 obtains cell current values I-cell_1 to I-cell_n of the memory cells M1 to Mn sequentially. The converter 123 converts the cell current values I-cell_1 to I-cell_n to current data DC1 to DCn of the memory cells M1 to Mn sequentially.

In the step S140, when the selected memory cell is the last memory cell, the test circuit 120 outputs a test result TR according to the current data DC1 to DCn in the step S150.

In the embodiment, the steps S110 to S150 have been clearly explained in the embodiments of FIG. 1, so it will not be repeated here.

Besides, the test method S100 could be used for the memory device 200.

In view of the foregoing, the test circuit in the memory device obtains the cell current values of the memory cells sequentially and converts the cell current values to the current data of the memory cells sequentially. The memory device can perform a self-test function to decrease a test time. In this way, the memory device decreases the test time for verifying the cell currents of the memory cells.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A memory device, comprising:
a memory array, comprising a plurality of memory cells;
a test circuit, comprising:
a select circuit, connected to the memory array, and configured to select one of the plurality of memory cells sequentially;
a current receiver, connected to the select circuit, and configured to obtain a plurality of cell current values of the plurality of memory cells sequentially; and
a converter, connected to the current receiver, and configured to convert the plurality of cell current values to a plurality of current data of the plurality of memory cells sequentially,
wherein the test circuit outputs a test result according to the plurality of current data.

2. The memory device of claim 1, wherein:
the plurality of memory cells comprises a first memory cell and a second memory cell,
when the first memory cell is selected by the select circuit, the current receiver obtains a first cell current value of the first memory cell, and then the converter converts the first cell current value to a first current data, and
when the second memory cell is selected by the select circuit, the current receiver obtains a second cell current value of the second memory cell, and then the converter converts the second cell current value to a second current data.

3. The memory device of claim 1, wherein the test circuit comprises:
a controller, connected to the converter, and configured to count a plurality of numbers of the plurality of memory cells corresponding to a plurality of cell current value ranges to generate a plurality of count values according to the plurality of current data.

4. The memory device of claim 3, further comprising:
a current data memory, connected to the controller, and configured to store the plurality of count values corresponding to the plurality of cell current value ranges,
wherein when the controller obtains a current data corresponding to a first cell current value range, the controller increments a first count values corresponding to the first cell current value range.

5. The memory device of claim 1, wherein the converter is implemented by an analog-to-digital converter.

6. The memory device of claim 1, wherein the converter converts a first cell current value among the plurality of cell current values to a plurality of sensing voltages, and converts the plurality of sensing voltages to a first current data among the plurality of current data having a serial format.

7. The memory device of claim 6, wherein the converter comprises:
a resistor string, connected between the current receiver and a reference low voltage, wherein the resistor string comprises a plurality of resistors connected in series each other through a plurality of nodes, wherein each of the plurality of nodes outputs a sensing voltage having different voltage value;
a plurality of comparators, connected to the plurality of nodes in one by one manner, and configured to compare a received sensing voltage among the plurality of sensing voltages and a reference voltage to generate a code bit of one of the plurality of current data respectively; and
a serializer, connected to the plurality of comparators, and configured to generate the plurality of current data having the serial format according to the plurality of sensing voltages.

8. The memory device of claim 7, wherein:
the resistor string comprises a first resistor and a second resistor,
the first resistor is connected between a first node and the reference low voltage,
the second resistor is connected between a second node and the first node, and
a voltage value of a first sensing voltage on the first node is lower than a voltage value of a second sensing voltage on the second node.

9. The memory device of claim 8, wherein:
a first comparator among the plurality of comparators is connected to the first node,
the first comparator compares the first sensing voltage and the reference voltage to generate a first code bit.

10. The memory device of claim 9, wherein:
when the voltage value of the first sensing voltage is higher than a voltage value of the reference voltage, the first code bit has a first logic level, and
when the voltage value of the first sensing voltage is lower than or equal to the voltage value of the reference voltage, the first code bit has a second logic level.

11. The memory device of claim 7, wherein each of the plurality of resistors has a same resistance value.

12. The memory device of claim 6, wherein the converter comprises:
a resistor string, connected between the current receiver and a reference low voltage, wherein the resistor string comprises a plurality of resistors connected in series each other through a plurality of nodes, wherein each of the plurality of nodes outputs a sensing voltage having different voltage value;
a multiplexer, connected to the plurality of nodes, and configured to select one of the plurality of sensing voltages as an output sensing voltage sequentially according to a select signal; and
a comparator, connected to the multiplexer, and configured to compare the output sensing voltage and a reference voltage to generate a code bit of one of the plurality of current data respectively.

13. The memory device of claim 12, wherein:
the resistor string comprises a first resistor and a second resistor,
the first resistor is connected between a first node and the reference low voltage,
the second resistor is connected between a second node and the first node, and
a voltage value of a first sensing voltage on the first node is lower than a voltage value of a second sensing voltage on the second node.

14. The memory device of claim 13, wherein the multiplexer selects the first sensing voltage as the output sensing voltage and then selects the second sensing voltage as the output sensing voltage.

15. The memory device of claim 14, wherein the comparator compares the output sensing voltage corresponding to the first sensing voltage and a reference voltage to generate a first code bit, and then compares the output sensing voltage corresponding to the second sensing voltage and a reference voltage to generate a second code bit.

16. The memory device of claim 15, wherein:
when a voltage value of the output sensing voltage corresponding to the first sensing voltage is higher than a voltage value of the reference voltage, the first code bit has a first logic level, and
when the voltage value of the output sensing voltage corresponding to the first sensing voltage is lower than or equal to the voltage value of the reference voltage, the first code bit has a second logic level.

17. A test method of a memory device, wherein the memory device comprises a memory array and a test circuit, wherein the memory array comprises a plurality of memory cells, wherein the test method comprises:
selecting, by the test circuit, one of the plurality of memory cells sequentially;
obtaining, by the test circuit, a plurality of cell current values of the plurality of memory cells sequentially;
converting, by the test circuit, the plurality of cell current values to a plurality of current data of the plurality of memory cells sequentially; and
outputting a test result according to the plurality of current data.

18. The test method of claim 17, further comprising:
counting a plurality of numbers of the plurality of memory cells corresponding to a plurality of cell current value ranges to generate a plurality of count values according to the plurality of current data.

19. The test method of claim 18, further comprising:
providing a current data memory to store the plurality of count values corresponding to the plurality of cell current value ranges; and
when obtaining a current data corresponding to a first cell current value range, incrementing a first count values corresponding to the first cell current value range.

20. The test method of claim 17, wherein the step of converting, the plurality of cell current values to the plurality of current data of the plurality of memory cells sequentially comprises:
converting the plurality of cell current values to a plurality of sensing voltages sequentially, and converts the plurality of sensing voltages to the plurality of current data having a serial format sequentially.
